(19) United States
(12) Patent Application Publication
(10) Pub. No.: US 2023/0178540 A1
(43) Pub. Date: Jun. 8, 2023

(54) SEMICONDUCTOR DEVICE

(71) Applicant: FUJI ELECTRIC CO., LTD., Kawasaki-shi (JP)

(72) Inventor: Takahide TANAKA, Kawasaki-shi (JP)

(73) Assignee: FUJI ELECTRIC CO., LTD., Kawasaki-shi (JP)

(21) Appl. No.: 17/974,708

(22) Filed: Oct. 27, 2022

(30) Foreign Application Priority Data
Dec. 7, 2021 (JP) 2021-198593

(51) Int. Cl. H01L 27/02; H01L 29/10; H01L 29/78; H03K 3/356; H02M 1/08; H03K 17/687

(52) U.S. Cl. CPC H01L 27/0255; H01L 29/1095; H01L 29/7831; H01L 29/7816; H03K 3/356017; H02M 1/08; H03K 17/6871; H03K 2217/0063; H03K 2217/0072

(57) ABSTRACT

A semiconductor device includes: a first conductivity type base body; a second conductivity type well region provided on the base body and formed with a high potential side circuit; a second conductivity type voltage blocking area provided to surround a periphery of the well region; a level shifter having a second conductivity type drift region provided on the base body, a second conductivity type carrier reception region provided in an upper part of the drift region, a first conductivity type base region provided in contact with the drift region, a first gate electrode provided on the base region, and a second conductivity type carrier supply region provided in an upper part of the base region; a first conductivity type isolation region provided between the voltage blocking area and the drift region on the base body; and a second gate electrode on the isolation region.

### CROSS-REFERENCE TO RELATED APPLICATION

This application claims benefit of priority under 35 USC 119 based on Japanese Patent Application No. 2021-198593 filed on Dec. 7, 2021, the entire contents of which are incorporated by reference herein.

### BACKGROUND OF THE INVENTION

### 1. Field of the Invention

The present invention relates to a semiconductor device.

### 2. Description of the Related Art

In a general high voltage integrated circuit (HVIC), an n-type well region is provided on a p-type semiconductor substrate. The n-type well region is provided with a high potential side circuit region (high side circuit region) where a high potential side circuit (high side circuit) is formed. A p-type region surrounding the n-type well region is provided with a low potential side circuit region (low side circuit region) where a low potential side circuit (low side circuit) is formed. Between the n-type well region and the p-type region, a high voltage diode referred to as a high voltage junction termination (HVJT) is formed, and, even when the potential of the high side circuit region is several hundreds of V higher than the potential of the low side circuit region, normal operation is achieved.

In common, a p-type well region is formed on the n-type well region of the high side circuit region. To the p-type well region, a VS potential, which is a reference potential of the high side circuit, is applied. To the n-type well region, a VB potential, which is a power supply potential of the high side circuit, is applied.

Further, a level shifter is required to transmit a signal from the low side circuit to the high side circuit. The level shifter generally contains a high voltage n-channel MOSFET having a drain region provided on the high side circuit region side and a gate electrode and a source region provided on the low side circuit region side. A drain potential (Dr potential) of the level shifter is connected to the VB potential by a level shift resistor. When a gate of the level shifter is off, the Dr potential of the level shifter is higher than the VS potential and is approximately equal to the VB potential (VB potential≈Dr potential>VS potential). On the other hand, when the gate of the level shifter is on, the Dr potential of the level shifter is lower than the VB potential and is approximately equal to the VS potential (VB potential>Dr potential≈VS potential).

In the case of a configuration referred to as a self-shielding system (SS system), the level shifter is formed utilizing a part of the HVJT. In the high side circuit region, an n-type drift region fixed to the Dr potential of the level shifter coexists with the n-type well region fixed to the VB potential and the p-type well region fixed to the VS potential. Therefore, there is a necessity of isolating the n-type well region and the n-type drift region from each other. For the isolation, a slit-shaped p-type isolation region is used. When an inversion layer is formed in the p-type isolation region due to surface charges or the like, the VB potential and the Dr potential are short-circuited, so that a signal cannot be correctly transmitted when the gate of the level shifter is turned on.

Thus, it is known that a shield layer is provided above the p-type isolation region such that the inversion layer is not formed in the p-type isolation region (see JP 3917211 B2 and JP 5733416 B2). JP 3917211 B2 discloses a configuration in which the shield layer is fixed to the Dr potential of the level shifter. JP 5733416 B2 discloses a configuration in which the shield layer is fixed to the VS potential.

### SUMMARY OF THE INVENTION

A conventional HVIC exhibits a behavior in which, when a negative voltage surge is applied to the n-type well region of the high side circuit region, the Dr potential of the level shifter temporarily increases to exceed the VB potential, and then decreases to be close to the VS potential, for example. At this time, when the decrease amount in the Dr potential is large, the Dr potential becomes approximately equal to the VS potential (Dr potential≈VS potential) even though the gate of the level shifter is not turned on, so that an output of the level shifter is sometimes erroneously inverted.

In view of the above-described problems, it is an object of the present invention to provide a semiconductor device capable of suppressing the malfunction of the level shifter due to a surge voltage in the HVIC.

An aspect of the present invention inheres in a semiconductor device including: a first conductivity type base body; a second conductivity type well region provided on the base body and formed with a high potential side circuit; a second conductivity type voltage blocking area provided to surround a periphery of the well region and having an impurity concentration lower than an impurity concentration of the well region; a level shifter having a second conductivity type drift region provided on the base body, a second conductivity type carrier reception region provided in an upper part of the drift region and having an impurity concentration higher than an impurity concentration of the drift region, a first conductivity type base region provided in contact with the drift region, a first gate electrode provided to be insulated on the base region, and a second conductivity type carrier supply region provided in an upper part of the base region; a first conductivity type isolation region provided between the voltage blocking area and the drift region on the base body; and a second gate electrode which is provided to be insulated on the isolation region and to which a first potential or a second potential higher than the first potential is alternatively applied.

### BRIEF DESCRIPTION OF THE DRAWINGS

FIG. 1 is a circuit diagram of a semiconductor device according to a first embodiment;

FIG. 2 is a plan view of the semiconductor device according to the first embodiment;

FIG. 3 is a cross-sectional view cut along the A-A′ line in FIG. 2;

FIG. 4 is another cross-sectional view cut along the A-A′ line in FIG. 2;

FIG. 5 is a graph illustrating a simulation result of a Dr-VS voltage when a VB-GND voltage is applied;

FIG. 6 is a circuit diagram of a switching circuit of the semiconductor device according to the first embodiment;

FIG. 7 is a timing chart of an operation of a switching circuit of the semiconductor device according to the first embodiment;

FIG. 8 is a graph illustrating changes in the Dr-VS voltage by the semiconductor device according to the first embodiment;

FIG. 9 is a cross-sectional view of a semiconductor device according to a first comparative example;

FIG. 10 is a cross-sectional view of a semiconductor device according to a second comparative example;

FIG. 11 is a cross-sectional view of a semiconductor device according to a second embodiment; and

FIG. 12 is a cross-sectional view of a semiconductor device according to a third embodiment.

### DETAILED DESCRIPTION

With reference to the Drawings, first to third embodiments of the present invention will be described below.

In the Drawings, the same or similar elements are indicated by the same or similar reference numerals. The Drawings are schematic, and it should be noted that the relationship between thickness and planer dimensions, the thickness proportion of each layer, and the like are different from real ones. Accordingly, specific thicknesses or dimensions should be determined with reference to the following description. Moreover, in some drawings, portions are illustrated with different dimensional relationships and proportions.

The first to third embodiments described below merely illustrate schematically devices and methods for specifying and giving shapes to the technical idea of the present invention, and the span of the technical idea is not limited to materials, shapes, structures, and relative positions of elements described herein.

In the Specification, a “carrier supply region” means a semiconductor region which supplies majority carriers as a main current. The carrier supply region is assigned to a semiconductor region which will be a source region in a field-effect transistor (FET) or a static induction transistor (SIT), an emitter region in an insulated-gate bipolar transistor (IGBT), and an anode region in a static induction (SI) thyristor or a gate turn-off (GTO) thyristor. A “carrier reception region” means a semiconductor region which receive the majority carriers as the main current. The carrier reception region is assigned to a semiconductor region which will be the drain region in the FET or the SIT, the collector region in the IGBT, and the cathode region in the SI thyristor or GTO thyristor.

In the Specification, definitions of directions such as an up-and-down direction in the following description are merely definitions for convenience of understanding, and are not intended to limit the technical ideas of the present invention. For example, as a matter of course, when the subject is observed while being rotated by 90°, the subject is understood by converting the up-and-down direction into the right-and-left direction. When the subject is observed while being rotated by 180°, the subject is understood by inverting the up-and-down direction.

In the Specification, there is exemplified a case where a first conductivity-type is an p-type and a second conductivity-type is a n-type. However, the relationship of the conductivity-types may be inverted to set the first conductivity-type to the n-type and the second conductivity-type to the p-type. Further, a semiconductor region denoted by the symbol “n” or “p” attached with “+” indicates that such semiconductor region has a relatively high impurity concentration as compared to a semiconductor region denoted by the symbol “n” or “p” without “+”. A semiconductor region denoted by the symbol “n” or “p” attached with “−” indicates that such semiconductor region has a relatively low impurity concentration as compared to a semiconductor region denoted by the symbol “n” or “p” without “−”. However, even when the semiconductor regions are denoted by the same reference symbols “n” and “n”, it is not indicated that the semiconductor regions have exactly the same impurity concentration. Moreover, the members and the regions that are limited by adding “first conductivity-type” and “second conductivity-type” in the following description indicate the members and the regions formed of semiconductor materials without particular obvious limitations.

### First Embodiment

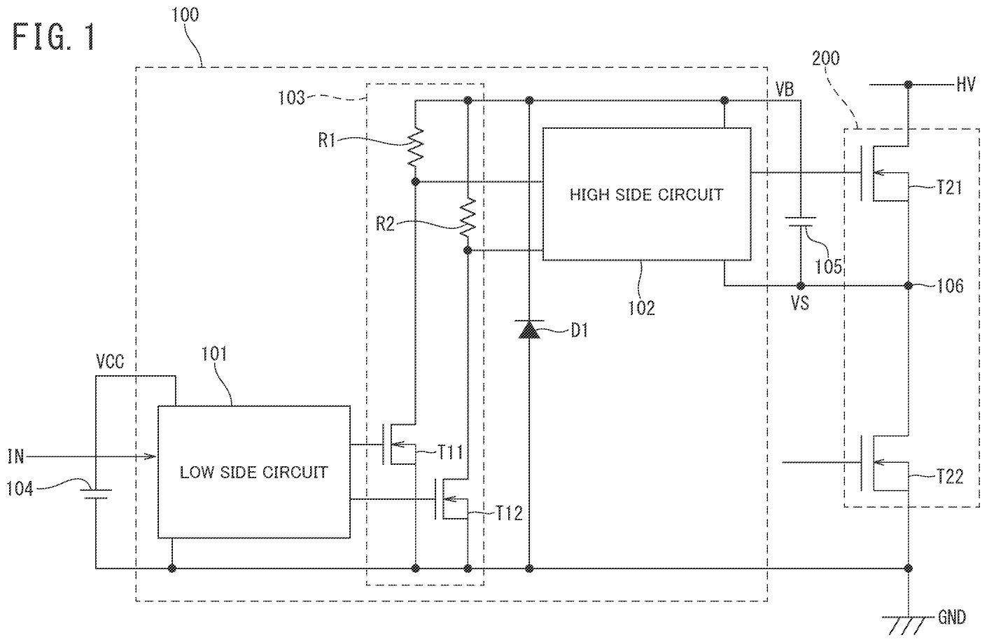

As illustrated in FIG. 1, a semiconductor device according to a first embodiment is an HVIC 100 driving a power conversion unit 200 forming one phase of a power conversion bridge circuit, for example, as a drive target. The power conversion unit 200 connects a high potential side switching element T21 and a low potential side switching element T22 in series to constitute a half-bridge circuit. FIG. 1 illustrates a metal oxide semiconductor field-effect transistor (MOSFET) as an example of the high potential side switching element T21 and the low potential side switching element T22. However, the high potential side switching element T21 and the low potential side switching element T22 may be the other power switching elements, such as IGBT.

A drain of the high potential side switching element T21 is connected to an HV potential on the high potential side. A source of the low potential side switching element T22 is connected to the ground potential (GND potential) on the low potential side. To a connection point 106 between a source of the high potential side switching element T21 and a drain of the low potential side switching element T22, a VS potential on the negative electrode side of a power supply (high potential side power supply) 105 on the high potential side and a load (not illustrated), such as a motor, are connected, and the VS potential is supplied to the load via the connection point 106.

The HVIC 100 applies a drive signal turning on/off a gate of the high potential side switching element T21 for driving to the gate of the high potential side switching element T21 in response to an input signal IN from an external microcomputer or the like. The HVIC 100 includes a low potential side circuit (low side circuit) 101, a level shift circuit 103, and a high potential side circuit (high side circuit) 102.

The low side circuit 101 is connected to a VCC potential which is a positive electrode side and a GND potential which is a negative electrode side of a power supply (low potential side power supply) 104 on the low potential side. The low side circuit 101 operates with the GND potential as a reference potential and with the VCC potential higher than the GND potential as a power supply potential. The low side circuit 101 generates an on/off signal based on the GND potential in response to the input signal IN from the external microcomputer or the like, and outputs the same to the level shift circuit 103.

The level shift circuit 103 converts the on/off signal based on the GND potential from the low side circuit 101 into an on/off signal based on the VS potential. The level shift circuit 103 includes level shifters T11, T12 and level shift resistors R1, R2. The level shifters T11, T12 contain an n-channel MOSFET, for example. Gates of the level shifters T11, T12 are connected to the low side circuit 101. Sources of the level shifters T11, T12 are connected to the GND potential. A drain of the level shifter T11 is connected to the high side circuit 102 and one end of the level shift resistor R1. The other end of the level shift resistor R1 is connected to a VB potential. A drain of the level shifter T12 is connected to the high side circuit 102 and one end of the level shift resistor R2. The other end of the level shift resistor R2 is connected to the VB potential. A cathode of the protection diode D1 is connected to the VB potential. An anode of the protection diode D1 is connected to the GND potential.

The high side circuit 102 operates with the VS potential as the reference potential and with the VB potential higher than the VS potential as the power supply potential. The high side circuit 102 outputs a drive signal to the gate of the high potential side switching element T21 in response to the on/off signal from the level shift circuit 103 to drive the gate of the high potential side switching element T21.

The high side circuit 102 includes, for example, a CMOS circuit containing an n-channel MOSFET and a p-channel MOSFET in the output stage.

The VB potential is the maximum potential applied to the HVIC 100 and is kept about 15 V higher than the VS potential under normal conditions not affected by noise. The VS potential repeatedly rises and falls between the HV potential on the high potential side (for example, about 400 V to 600 V) and the GND potential on the low potential side by turning on/off the high potential side switching element T21 and the low potential side switching element T22 in a complementary manner, and fluctuates between 0 V and several hundreds of V. The VS potential sometimes becomes a negative potential.

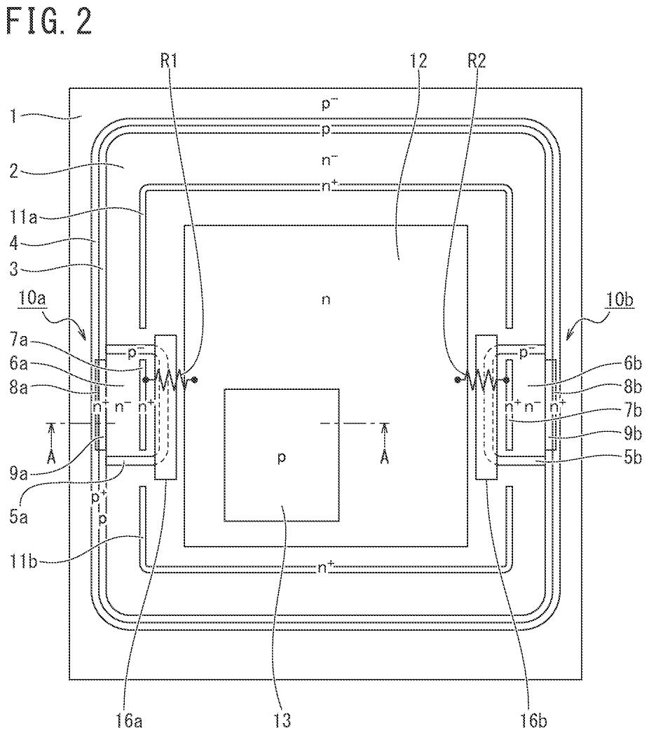

FIG. 2 illustrates the planar layout of the HVIC 100. The HVIC 100 includes a high potential side circuit region (high side circuit region) 12 provided on a first conductivity type (p⁻-type) base body (semiconductor chip) 1. The p⁻-type base body 1 contains a silicon (Si) substrate, for example. The base body 1 may contain a semiconductor substrate, such as silicon carbide (SiC), gallium nitride (GaN), gallium arsenide (GaAs), or diamond. The base body 1 may contain a p⁻-type epitaxial layer provided on the semiconductor substrate.

The high side circuit region 12 corresponds to the high side circuit 102 illustrated in FIG. 1. As illustrated in FIG. 2, the high side circuit region 12 has a substantially rectangular planar pattern. The high side circuit region 12 contains a second conductivity type (n-type) well region. To the high side circuit region 12, the VB potential is applied. In an upper part of the high side circuit region 12, a p-type well region 13 is provided. To the well region 13, the VS potential is applied. FIG. 2 does not illustrate various elements included in the high side circuit region 12 and the well region 13.

A voltage blocking area 2 containing a high voltage junction termination (HVJT) is provided in an annular shape to surround the high side circuit region 12. The voltage blocking area 2 electrically isolates the high side circuit region 12 on the inner peripheral side of the voltage blocking area 2 and a low potential side circuit region (low side circuit region) formed on the base body 1 on the outer peripheral side of the voltage blocking area 2 from each other. The low side circuit region formed on the base body 1 corresponds to the low side circuit 101 in FIG. 1. FIG. 2 does not illustrate various elements included in the low side circuit region. In an upper part of the voltage blocking area 2, n⁺-type contact regions 11a, 11b are provided in a C-shape or a U-shape. To the contact regions 11a, 11b, the VB potential is applied.

A p-type base region 3 is provided in an annular shape to surround the voltage blocking area 2. The voltage blocking area 2 constitutes a high voltage diode by p-n junction with the base region 3. The high voltage diode corresponds to the protection diode D1 illustrated in FIG. 1. A p⁺-type base contact region 4 is provided in an annular shape in contact with the base region 3 to surround the outer periphery of the base region 3. To the base contact region 4, the GND potential is applied. The outer periphery of the base contact region 4 is surrounded by the base body 1.

Level shifters 10a, 10b are individually provided in parts of the voltage blocking area 2. The arrangement positions of the level shifters 10a, 10b are not particularly limited, and may be provided in parts of the voltage blocking area 2. The level shifters 10a, 10b correspond to the level shifters T11, T12 illustrated in FIG. 1. The level shifters 10a, 10b contain a high voltage n-channel MOSFET.

The level shifters 10a, 10b are formed by the SS system in which the periphery is surrounded by slit-shaped p⁻-type isolation regions (slit regions) 5a, 5b, respectively. More specifically, the p⁻-type isolation region 5a is provided on the periphery of the level shifter 10a. The isolation region 5a surrounds the periphery of the level shifter 10a in a C-shape or U-shape, and the end of the isolation region 5a is in contact with the base region 3. The level shifter 10a includes an n⁻-type drift region 6a, an n⁺-type carrier reception region (drain region) 7a, an n⁺-type carrier supply region (source region) 8a, and a control electrode (gate electrode) 9a. The drift region 6a contains a part of the voltage blocking area 2, and is electrically isolated from the voltage blocking area 2 by the isolation region 5a. The drain region 7a, the source region 8a, and the gate electrode 9a have linear planar shapes extending parallel to each other, for example. The drain region 7a is connected to the high side circuit region 12 via the level shift resistor R1. A gate electrode 16a is provided on a part extending parallel to the drain region 7a of the isolation region 5a. The gate electrode 16a has a linear planar shape extending parallel to the drain region 7a.

On the periphery of the level shifter 10b, a p⁻-type isolation region 5b is provided. The isolation region 5b surrounds the periphery of the level shifter 10b in a C-shape or a U-shape, and the end of the isolation region 5b is in contact with the base region 3. The level shifter 10b includes an n⁻-type drift region 6b, an n⁺-type drain region 7b, an n⁺-type source region 8b, and a gate electrode 9b. The drift region 6b contains a part of the voltage blocking area 2, and is electrically isolated from the voltage blocking area 2 by the isolation region 5b. The drain region 7b, the source region 8b, and the gate electrode 9b have linear planar shapes extending parallel to each other, for example. The drain region 7b is connected to the high side circuit region 12 via the level shift resistor R2. A gate electrode 16b is provided on a part extending parallel to the drain region 7b of the isolation region 5b. The gate electrode 16b has a linear planar shape extending parallel to the drain region 7b.

The following description is given focusing on a peripheral region containing the level shifter 10a and the gate electrode 16a of one of the two level shifters 10a, 10b, but the configuration of a peripheral region containing the other level shifter 10b and the gate electrode 16b of one of the two level shifters 10a, 10b also has the same configuration as that of a peripheral region containing the level shifter 10a and the gate electrode 16a.

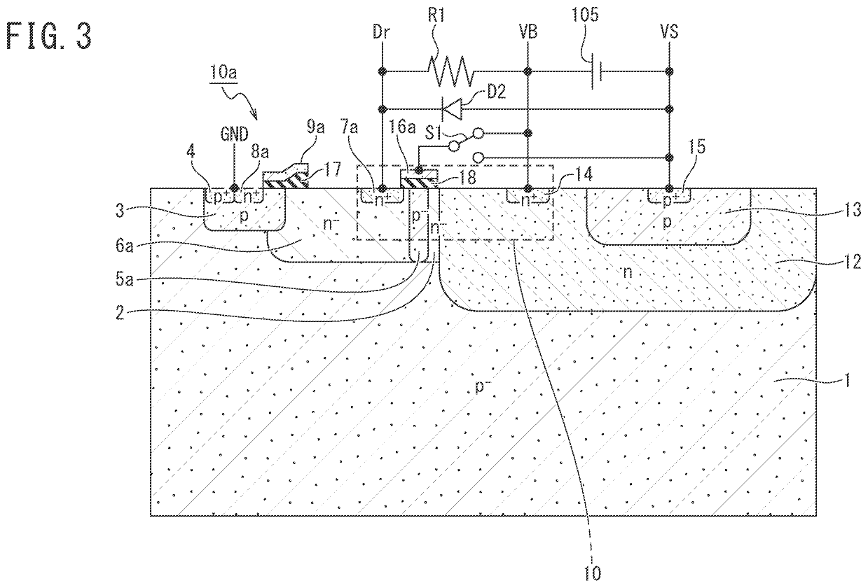

FIG. 3 is a cross-sectional view cut along the A-A′ line passing through the level shifter 10a in FIG. 2. As illustrated in FIG. 3, the n-type high side circuit region 12 is provided in an upper part of the p⁻-type base body 1. In an upper part of the high side circuit region 12, an n⁺-type contact region 14 is provided which has an impurity concentration higher than that of the high side circuit region 12. The contact region 14 is not illustrated in FIG. 2. To the contact region 14, the level shift resistor R1 and the VB potential on the positive electrode side of the high potential side power supply 105 are connected.

In the upper part of the high side circuit region 12, the p-type well region 13 is provided apart from the contact region 14. In an upper part of the well region 13, a p⁺-type contact region 15 is provided which has an impurity concentration higher than that of the well region 13. The contact region 15 is not illustrated in FIG. 2. To the contact region 15, the VS potential on the negative electrode side of the high potential side power supply 105 and an anode of the protection diode D2 are connected.

In an upper part of the p⁻-type base body 1, the n⁻-type voltage blocking area 2 is provided which is in contact with the high side circuit region 12 and has an impurity concentration lower than that of the high side circuit region 12. In an upper part of the p⁻-type base body 1, the p⁻-type isolation region 5a is provided in contact with the voltage blocking area 2.

In an upper part of the p⁻-type base body 1, the level shifter 10a is provided which is electrically isolated from the high side circuit region 12 by the isolation region 5a. In an upper part of the p⁻-type base body 1, the n⁻-type drift region 6a is selectively provided in contact with the isolation region 5a. The isolation region 5a electrically isolates the voltage blocking area 2 and the drift region 6a from each other. In an upper part of the drift region 6a, the n⁺-type drain region 7a is provided which has an impurity concentration higher than that of the drift region 6a. To the drain region 7a, the level shift resistor R1 and a cathode of the protection diode D2 are connected.

In an upper part of the p⁻-type base body 1, the p-type base region 3 is selectively provided which is in contact with the drift region 6a and has an impurity concentration higher than that of the base body 1. In an upper part of the base region 3, the n⁺-type source region 8a is selectively provided. In an upper part of the base region 3, the p⁺-type base contact region 4 is selectively provided which is in contact with the source region 8a and has an impurity concentration higher than that of the base region 3. To the source region 8a and the base contact region 4, the GND potential is connected.

On the base region 3, the gate electrode 9a is provided to extend from the top of the source region 8a to the top of the drift region 6a and to be insulated via a gate insulating film 17. The gate insulating film 17 can be formed of a silicon oxide film (SiO₂ film), various insulating films, such as a silicon nitride film (Si₃N₄ film), other than the SiO₂ film, or a laminated film of the insulating films including the SiO₂ film, the Si₃N₄ film, and the like. The gate electrode 9a is formed of polycrystalline silicon (doped polysilicon) films into which impurities are doped, refractory metals, refractory metal silicides, or the like, for example. The gate electrode 9a controls a surface potential of the base region 3 and controls the flow of a main current flowing between the source region 8a and the drain region 7a.

When a gate of the level shifter 10a is off, the drain potential (Dr potential) of the drain region 7a of the level shifter 10a is higher than the VS potential and is approximately equal to the VB potential (VB potential≈Dr potential>VS potential). On the other hand, when the gate of the level shifter 10a is on, the Dr potential of the level shifter 10a is lower than the VB potential and is approximately equal to the VS potential (VB potential>Dr potential≈VS potential).

On the isolation region 5a, a gate electrode (shield layer) 16a is provided to extend from the top of the voltage blocking area 2 to the top of the drift region 6a and to be insulated via a gate insulating film 18. The gate insulating film 18 may contain a material the same as or different from the material of the gate insulating film 17 under the gate electrode 9a. The gate electrode 16a is formed of polycrystalline silicon (doped polysilicon) films into which impurities are doped, refractory metals, refractory metal silicides, or the like, for example. The gate electrode 16a may contain metals, such as aluminum (Al), or may contain the other conductive materials. The gate electrode 16a may contain a material the same as or different from the material of the gate electrode 9a.

To the gate electrode 16a, a switching circuit S1 is connected. The potential of the gate electrode 16a is alternatively switchable between the VS potential (first potential) on the negative electrode side of the high potential side power supply 105 and the VB potential (second potential) on the positive electrode side of the high potential side power supply 105 by the switching circuit S1. More specifically, an n-channel MOSFET 10 is constituted which contains the drain region 7a as the source region, the isolation region 5a as the base region, the contact region 14 as the drain region, and the voltage blocking area 2 and the high side circuit region 12 as the drift regions, and the gate electrode 16a functions as a gate electrode of the n-channel MOSFET 10. The gate electrode 16a controls a surface potential of the isolation region 5a, and controls the flow of a main current flowing between the source region which is the drain region 7a of the level shifter 10a and the drain region which is the contact region 14.

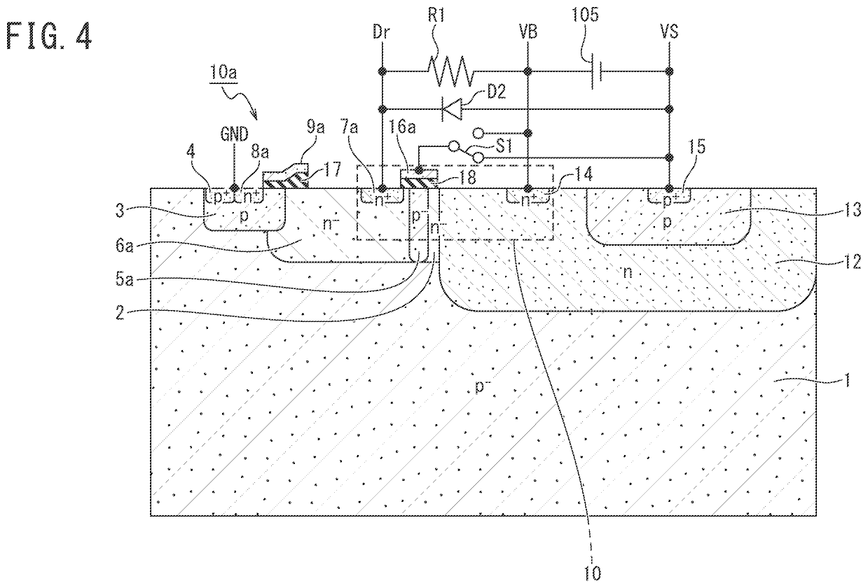

By switching the potential of the gate electrode 16a between the VB potential and the VS potential, the n-channel MOSFET 10 can be turned on/off at desired timing. As illustrated in FIG. 3, when the potential of the gate electrode 16a is fixed to the VS potential, the n-channel MOSFET is turned off, and the VB potential and the Dr potential is connected only by the level shift resistor R1. On the other hand, as illustrated in FIG. 4, when the switching circuit Si switches the connection destination of the gate electrode 16a, so that the potential of the gate electrode 16a is fixed to the VB potential, the n-channel MOSFET is turned on, and the VB potential and the Dr potential are short-circuited.

When the Dr potential of the level shifter 10a is always equal to or lower than the VB potential (Dr potential≤VB potential) during normal operation, the switching circuit S1 is controlled so that the potential of the gate electrode 16a is fixed to the VS potential. In this case, the n-channel MOSFET is turned off, and the gate electrode 16a functions as a shield (field plate) preventing the formation of an inversion layer in the isolation region 5a due to surface charges or the like. Thus, the VB potential and the Dr potential can be prevented from being short-circuited and the malfunction of the level shifter 10a can be prevented.

On the other hand, during abnormal operation under specific conditions other than the normal operation, the switching circuit S1 detects the abnormal operation and is controlled to temporarily fix the potential of the gate electrode 16a to the VB potential. For example, the switching circuit Si detects the Dr potential of the level shifter 10a, and, when the detected Dr potential of the level shifter 10a becomes higher than the VB potential, the switching circuit S1 is controlled to temporarily fix the potential of the gate electrode 16a to the VB potential. In this case, the n-channel MOSFET is turned on to short-circuit between the VB potential and the Dr potential, so that the malfunction of the level shifter 10a can be prevented.

As the abnormal operation, a behavior is known in which, when a negative voltage surge is applied to the high side circuit region 12, a high voltage diode constituted by the p-n junction between the voltage blocking area 2 and the base region 3 is forward biased, so that the Dr potential of the level shifter 10a temporarily increases, exceeds the VB potential, and then decreases to be close to the VS potential, for example.

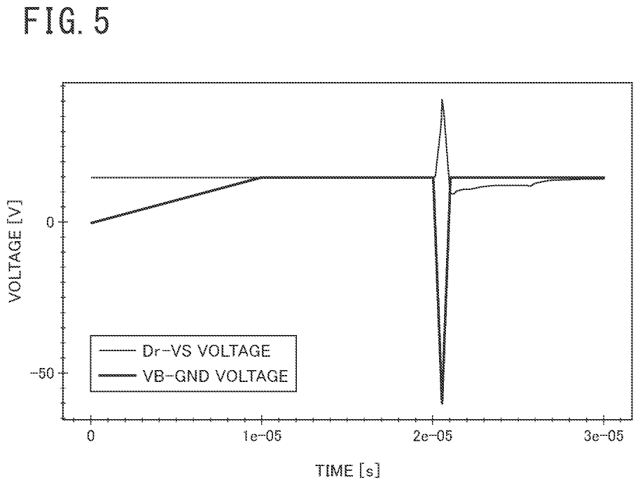

FIG. 5 illustrates a simulation result of applying the negative voltage surge when the potential of the gate electrode 16a is fixed to be equal to or lower than the Dr potential. A VB-GND voltage (thick solid line) is temporarily negatively biased from +15 V, and then returned to the original +15 V. At this time, a Dr-VS voltage (thin solid line) exhibits a behavior of exceeding the VB potential during the period when the VB-GND voltage is a negative voltage, and then decreases. When the decrease amount of the Dr potential at this time is large, the Dr potential becomes approximately equal to the VS potential (Dr potential≈VS potential) even though the level shifter 10a is not turned on, so that an output of the level shifter 10a may be erroneously inverted.

To address such an abnormal operation mode, in the semiconductor device according to the first embodiment, the switching circuit S1 detects the abnormal operation and switches the connection destination of the gate electrode 16a to the VB potential to turn on the n-channel MOSFET 10, so that the Dr potential is short-circuited to the VB potential, and a decrease in the Dr potential is suppressed. For example, the n-channel MOSFET 10 is temporarily turned on with the timing when the Dr potential, which is equal to or lower than the VB potential during the normal operation, exceeds the VB potential during the abnormal operation as a trigger.

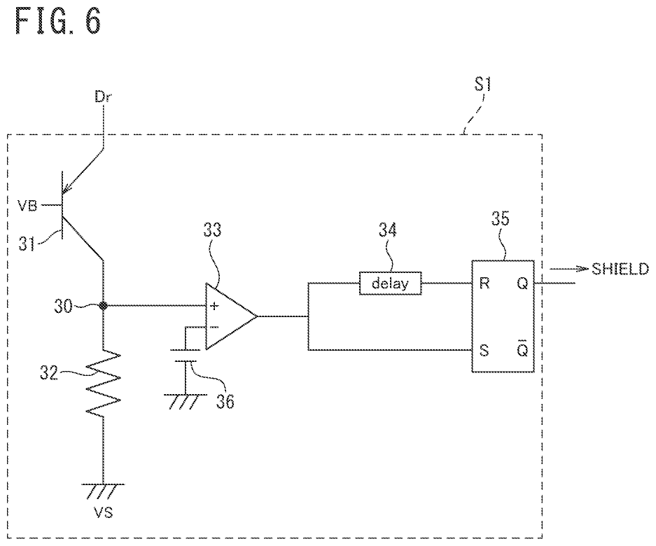

FIG. 6 illustrates an example of the configuration of the switching circuit S1. As illustrated in FIG. 6, the switching circuit S1 includes a pnp transistor 31, a resistor 32, a comparator 33, a delay circuit 34, and a latch circuit 35, for example. An emitter of the pnp transistor 31 is connected to the Dr potential. A base of the pnp transistor 31 is connected to the VB potential. To a collector of the pnp transistor 31, the VS potential is connected via the resistor 32.

To a connection point 30 between the collector of the pnp transistor 31 and the resistor 32, a non-inverted input terminal of the comparator 33 is connected. The reference potential on the positive electrode side of a reference power supply 36 is connected to the inverted input terminal of the comparator 33. The reference power supply 36 may be a power supply that uses the VS potential as a reference potential. During the normal operation, the Dr potential is equal to or lower than the VB potential (Dr potential≤VB potential), and the potential of the connection point 30 between the collector of the pnp transistor 31 and the resistor 32 is equal to or lower than the VS potential, and an output of the comparator 33 becomes low (VS potential). On the other hand, when the negative voltage surge is applied, the Dr potential momentarily exceeds the VB potential (Dr potential>VB potential), and the potential of the connection point 30 becomes larger than the VS potential, and the output of the comparator 33 becomes high (VB potential).

To an output terminal of the comparator 33, a delay circuit 34 and a setting input terminal S of the latch circuit 35 are connected. A resetting input terminal R of the latch circuit 35 is connected to the output terminal of the comparator 33 via the delay circuit 34. The delay circuit 34 transmits an output of the comparator 33 to the input terminal R of the latch circuit 35 while delaying the output by a predetermined time. More specifically, the same signal as that of the input terminal S is input into the input terminal R of the latch circuit 35 via the delay circuit 34.

The gate electrode 16a is connected to an output terminal Q of the latch circuit 35. The latch circuit 35 outputs a H-level VB potential or a L-level VS potential from the output terminal Q according to the states of the input terminal S and the input terminal R, and applies the H-level VB potential or the L-level VS potential to the gate electrode 16a. During the normal operation, the output terminal Q of the latch circuit 35 becomes low (VS potential). On the other hand, when the negative voltage surge is applied, the output terminal Q of the latch circuit 35 temporarily becomes high (VB potential) according to high (VB potential) of the input terminal S, and thereafter, when the input terminal R becomes high (VB potential), the output terminal Q of the latch circuit 35 returns to be low (VS potential). The configuration of the switching circuit S1 illustrated in FIG. 6 is an example, and the switching circuit S1 may be realized by the other configuration. The switching circuit S1 can be formed in the high side circuit region 12 illustrated in FIG. 2, for example.

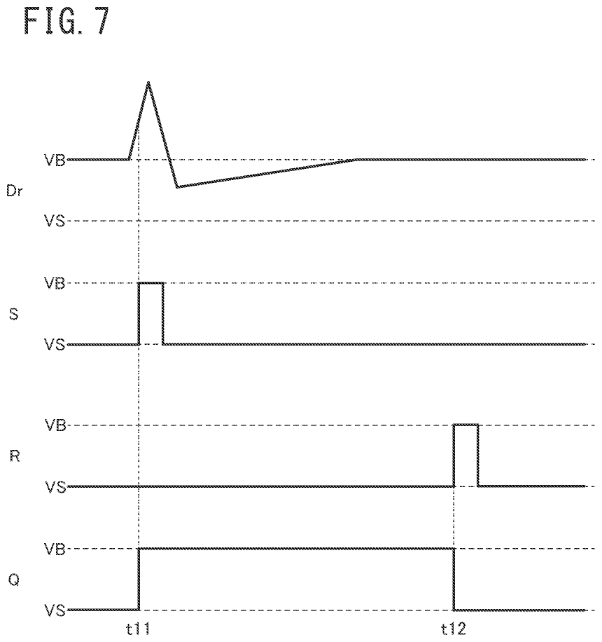

Next, the operation of the switching circuit S1 illustrated in FIG. 6 is described with reference to the timing chart of FIG. 7. In the timing chart of FIG. 7, the Dr potential is indicated as “Dr”, an input of the input terminal S of the latch circuit 35 is indicated as “S”, an input of the input terminal R of the latch circuit 35 is indicated as “R”, and an output of the output terminal Q of the latch circuit 35 indicated as “Q”.

Before a time t11, the output of the output terminal Q of the latch circuit 35 is low (VS potential), and the gate electrode 16a is fixed to the VS potential. When the negative voltage surge is applied, the Dr potential momentarily exceeds the VB potential. At the time t11, the output of comparator 33 becomes high (VB potential), and the input of the input terminal S of the latch circuit 35 is switched from low (VS potential) to high (VB potential). On the other hand, the input of the input terminal R of the latch circuit 35 maintains low (VS potential). Therefore, the output of the output terminal Q of the latch circuit 35 is switched from low (VS potential) to high (VB potential), and the gate electrode 16a is fixed to the VB potential.

The timing from when the Dr potential exceeds the VB potential to the time t11 can be adjusted as appropriate. Immediately after the Dr potential exceeds the VB potential, the output of the latch circuit 35 may be set to high (VB potential) or the output of the latch circuit 35 may be set to high (VB potential) after the Dr potential exceeds the VB potential by a predetermined threshold voltage.

From the time t11 to a time t12, the output of the output terminal Q of the latch circuit 35 is fixed to high (VB potential). At the time t12, high (VB potential) is output with a delay from the delay circuit 34, and the input of the input terminal R of the latch circuit 35 is switched from low (VS potential) to high (VB potential). The output of the output terminal Q of the latch circuit 35 returns from high (VB potential) to low (VS potential). The predetermined time (fixed time) from the time t11 to the time t12 can be adjusted as appropriate by adjusting the delay time of the delay circuit 34, for example, according to the type of a surge voltage or the like.

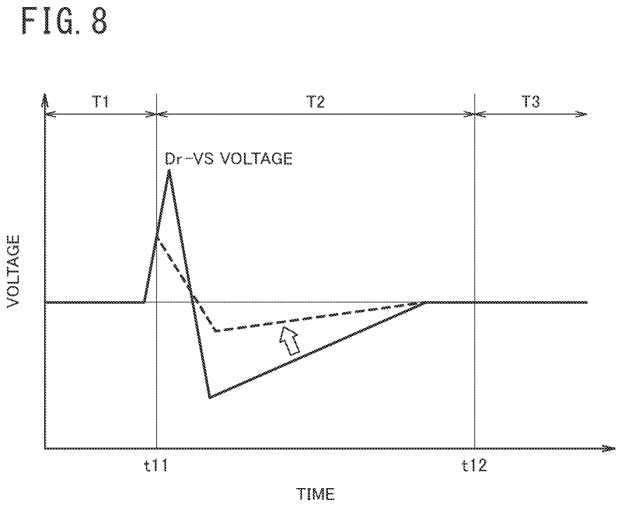

FIG. 8 illustrates a behavior of the Dr potential when the negative voltage surge is applied. The solid line in FIG. 8 indicates a behavior of a conventional Dr potential when the negative voltage surge is applied. The broken line in FIG. 8 indicates a behavior of the Dr potential in the semiconductor device according to the first embodiment when the negative voltage surge is applied. The times t11, t12 in FIG. 8 correspond to the times t11, t12, respectively, illustrated in FIG. 7.

As illustrated in FIG. 8, at the time T1 before the time t11, the gate electrode 16a is connected to the VS potential and the n-channel MOSFET 10 is turned off. At the time t11, the connection destination of the gate electrode 16a is switched from the VS potential to the VB potential for a certain period of time T2 from the time t11 to the time t12 with the timing when the Dr potential exceeds the VB potential as a trigger, and the n-channel MOSFET 10 is turned on, so that the Dr potential is short-circuited with the VB potential, and a decrease in the Dr potential illustrated by the broken line in FIG. 8 can be suppressed as compared with a decrease in the conventional Dr potential illustrated by the solid line in FIG. 8. At a time T3 after the time t12, the connection destination of the gate electrode 16a is switched from the VB potential to the VS potential and the n-channel MOSFET 10 is turned off, so that the gate electrode 16a functions as a shield (field plate).

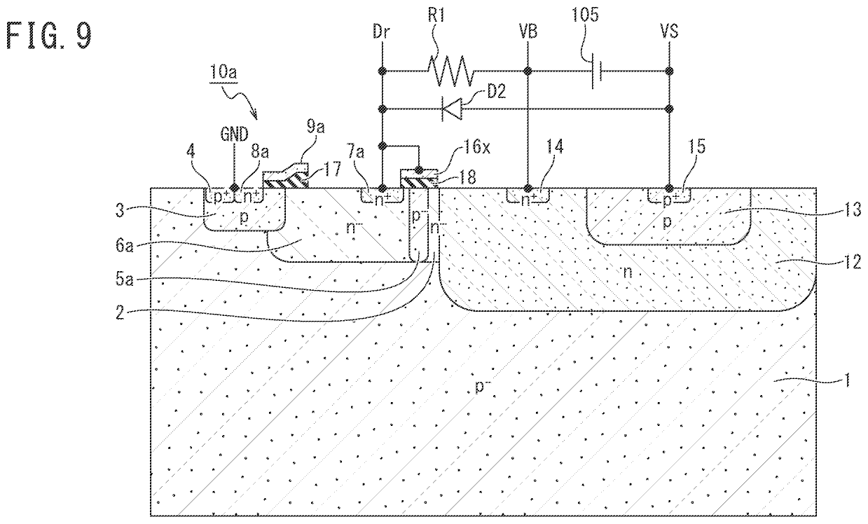

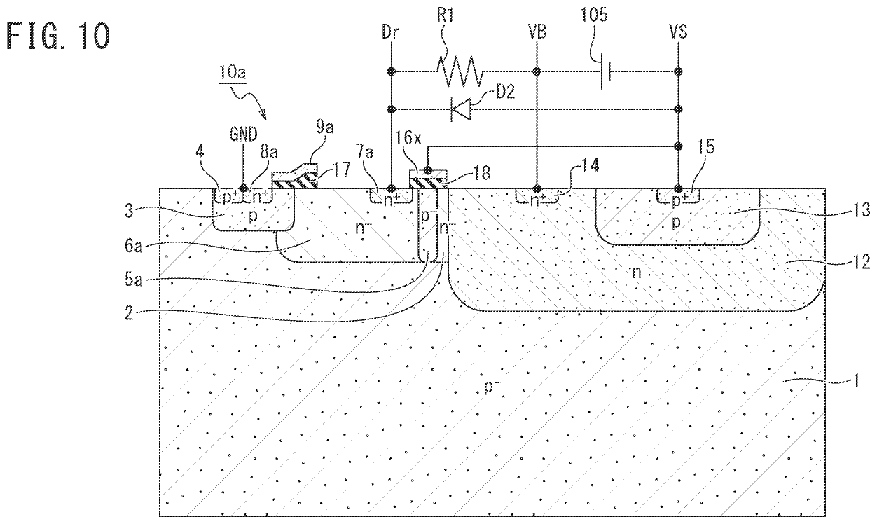

Herein, semiconductor devices according to the first and second comparative examples are described. As illustrated in FIG. 9, the semiconductor device according to the first comparative example is different from the semiconductor device according to the first embodiment illustrated in FIG. 3 in that a shield layer 16x fixed to the Dr potential of the level shifter 10a is provided above the p⁻-type isolation region 5a. As illustrated in FIG. 10, the semiconductor device according to the second comparative example is different from the semiconductor device according to the first embodiment illustrated in FIG. 3 in that a shield layer 16x fixed to the VS potential is provided above the p⁻-type isolation region 5a. In each of the semiconductor devices according to the first and second comparative examples, the potential of the shield layer 16x is equal to or lower than the Dr potential, and the shield layer 16x function as only a shield preventing the formation of an inversion layer in the p⁻-type isolation region 5a.

According to the semiconductor device of the first embodiment, the gate electrode 16a is provided above the p⁻-type isolation region 5a and the on/off of the n-channel MOSFET 10 is controlled in contrast with the semiconductor devices according to the first and second comparative examples. Therefore, during normal operation, the gate electrode 16a can be made to function as a shield as with the shield layer 16x of the semiconductor devices according to the first and second comparative examples and, during abnormal operation, the n-channel MOSFET 10 can be temporarily turned on by the gate electrode 16a, so that the malfunction of the level shifter 10a can be suppressed.

### Second Embodiment

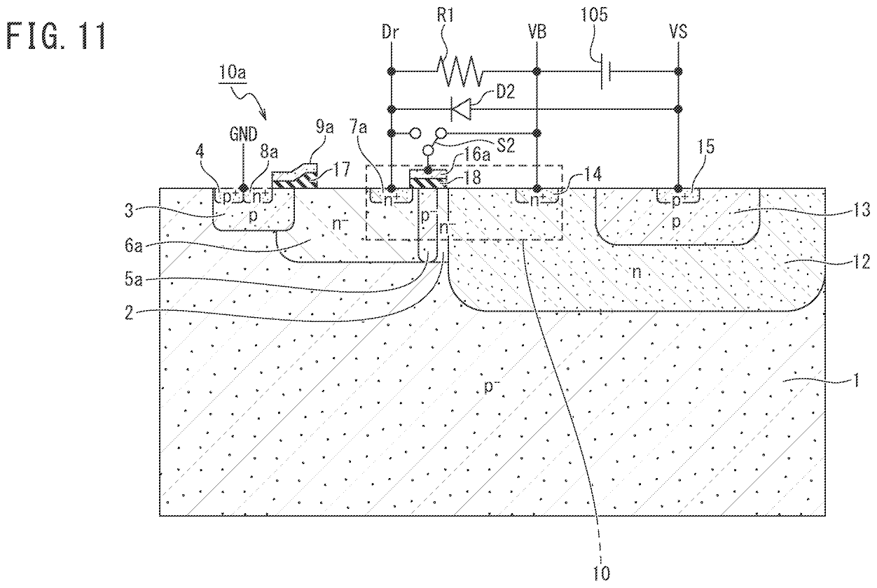

As illustrated in FIG. 11, the semiconductor device according to the second embodiment is different from the semiconductor device according to the first embodiment illustrated in FIG. 3 in that the switching circuit S2 can switch the potential of the gate electrode 16a between the Dr potential of the level shifter 10a instead of the VS potential on the negative electrode side of the high potential side power supply 105 and the VB potential on the positive electrode side of the high potential side power supply 105.

During normal operation, when the Dr potential of the level shifter 10a is equal to or lower than the VB potential (Dr potential≤VB potential), the potential of the gate electrode 16a is fixed to the Dr potential. On the other hand, during abnormal operation, when the Dr potential of the level shifter 10a exceeds the VB potential (Dr potential>VB potential), the switching circuits S2 detects the state as the abnormal operation and temporarily switches the connection destination of the gate electrode 16a to the VB potential as illustrated in FIG. 3. The other configurations of the semiconductor device according to the second embodiment are substantially the same as those of the semiconductor device according to the first embodiment, and therefore duplicate descriptions are omitted.

The semiconductor device according to the second embodiment exhibits the same effects as those of the semiconductor device according to the first embodiment, even when the switching circuit S2 switches the potential of the gate electrode 16a between the Dr potential of the level shifter 10a and the VB potential on the positive electrode side of the high potential side power supply 105.

### Third Embodiment

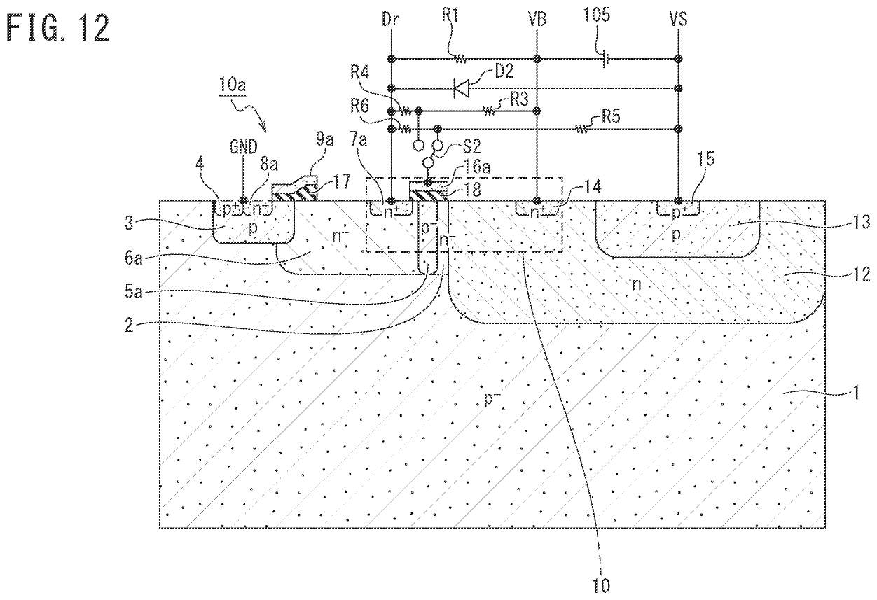

As illustrated in FIG. 12, the semiconductor device according to the third embodiment is the same as the semiconductor devices according to the second embodiment illustrated in FIG. 11 in that the switching circuit S2 can switch the potential of the gate electrode 16a between the Dr potential of the level shifter 10a and the VB potential on the positive electrode side of the high potential side power supply 105. However, the semiconductor device according to the third embodiment is different from the semiconductor device according to the second embodiment in that resistors R3, R4 connected between one end of the switching circuit S2 and the VB potential and the Dr potential and resistors R5, R6 connected between the other end of the switching circuit S2 and the VS potential and the Dr potential are further provided.

The resistance values of the resistors R3, R4, R5, and R6 can be individually adjusted as appropriate. The potential of the gate electrode 16a is switchable between a potential equal to or higher than the VS potential and equal to or lower than the Dr potential when the switching circuit S2 is connected to the resistors R5, R6 side and a potential equal to or higher than the Dr potential and equal to or lower the VB potential when the switching circuit S2 is connected to the resistors R3, R4 side. The other configurations of the semiconductor device according to the third embodiment are substantially the same as those of the semiconductor device according to the second embodiment, and therefore duplicate descriptions are omitted.

The semiconductor device according to the third embodiment exhibits the same effects as those of the semiconductor device according to the first embodiment even when the potential of the gate electrode 16a is switched between an intermediate potential between the VS potential and the Dr potential and an intermediate potential between the VB potential on the positive electrode side of the high potential side power supply 105 and the Dr potential. The configuration of switching the potential of the gate electrode 16a between the intermediate potential between the VS potential and the Dr potential and the intermediate potential between the VB potential and the Dr potential on the positive electrode side of the high potential side power supply 105 can be realized also by configurations other than the configuration of further including the resistors R3, R4, R5, R6.

### Other Embodiments

As described above, the invention has been described according to the first to third embodiments, but it should not be understood that the description and drawings implementing a portion of this disclosure limit the invention. Various alternative embodiments of the present invention, examples, and operational techniques will be apparent to those skilled in the art from this disclosure.

For example, the HVIC is illustrated as an example of the semiconductor devices according to the first to third embodiments, but the present invention is applicable also to semiconductor devices other than the HVIC insofar as a shield layer can be arranged above an isolation region. For example, the present invention is particularly effective for semiconductor devices to which a high voltage of several tens of V or more is applied.

The respective configurations disclosed in the first to third embodiments of the present invention and the respective modified examples can be combined together as necessary within a range without contradicting each other. As described above, the invention includes various embodiments of the present invention and the like not described herein. Therefore, the scope of the present invention is defined only by the technical features specifying the present invention, which are prescribed by claims, the words and terms in the claims shall be reasonably construed from the subject matters recited in the present Specification.

What is claimed is:

1. A semiconductor device comprising:
a first conductivity type base body;
a second conductivity type well region provided on the base body and formed with a high potential side circuit;
a second conductivity type voltage blocking area provided to surround a periphery of the well region and having an impurity concentration lower than an impurity concentration of the well region;
a level shifter having a second conductivity type drift region provided on the base body, a second conductivity type carrier reception region provided in an upper part of the drift region and having an impurity concentration higher than an impurity concentration of the drift region, a first conductivity type base region provided in contact with the drift region, a first gate electrode provided to be insulated on the base region, and a second conductivity type carrier supply region provided in an upper part of the base region;
a first conductivity type isolation region provided between the voltage blocking area and the drift region on the base body; and
a second gate electrode which is provided to be insulated on the isolation region and to which a first potential or a second potential higher than the first potential is alternatively applied.

2. The semiconductor device of claim 1, wherein
the first potential is equal to or higher than a potential on a negative electrode side of a power supply connected to the high potential side circuit and equal to or lower than a potential of the carrier reception region, and
the second potential is equal to or higher than the potential of the carrier reception region and equal to or lower than a potential on a positive electrode side of the power supply.

3. The semiconductor device of claim 1, wherein
the first potential is a potential on a negative electrode side of a power supply connected to the high potential side circuit, and
the second potential is a potential on a positive electrode side of the power supply connected to the high potential side circuit.

4. The semiconductor device of claim 1, wherein
the first potential is a potential of the carrier reception region, and
the second potential is a potential on a positive electrode side of a power supply connected to the high potential side circuit.

5. The semiconductor device of claim 1, wherein
the first potential is applied to the second gate electrode during normal operation, and
the second gate electrode is fixed to the second potential during abnormal operation.

6. The semiconductor device of claim 1, wherein
when a potential of the carrier reception region is equal to or lower than a potential on a positive electrode side of a power supply connected to the high potential side circuit, the first potential is applied to the second gate electrode, and
when the potential of the carrier reception region exceeds the potential on the positive electrode side of the power supply connected to the high potential side circuit, the second potential is temporarily applied to the second gate electrode.

7. The semiconductor device of claim 1, further comprising:
a switching circuit configured to detect a potential of the carrier reception region and switch the first potential or the second potential applied to the second gate electrode according to the detected potential of the carrier reception region.
